(19) United States
(12) Patent Application Publication
(10) Pub. No.: US 2026/0221982 A1
(43) Pub. Date: Jul. 30, 2026

(54) FOREGROUND SELF-CALIBRATION METHOD FOR SPLIT SUCCESSIVE-APPROXIMATION REGISTER ANALOG-TO-DIGITAL CONVERTER AND THE APPARATUS THEREOF

(71) Applicant: Industry-University Cooperation Foundation Hanyang University ERICA Campus, Ansan-si Gyeonggi-do (KR)

(72) Inventors: Byoungho KIM, Ansan-si (KR); Joonsung PARK, Ansan-si (KR)

(73) Assignee: Industry-University Cooperation Foundation Hanyang University ERICA Campus, Ansan-si Gyeonggi-do (KR)

(21) Appl. No.: 19/407,181

(22) Filed: Dec. 3, 2025

(30) Foreign Application Priority Data
Dec. 4, 2024 (KR) 10-2024-0178780

(51) Int. Cl. H03M 1/10; H03M 1/46

(52) U.S. Cl. CPC H03M 1/1014; H03M 1/462; H03M 1/466

(57) ABSTRACT

The present invention relates to a foreground self-calibration method for a split successive-approximation register analog-to-digital converter (SAR ADC) and an apparatus thereof, which restores a binary-weighted relationship between capacitors through a designed platform and improves overall linearity and performance of the SAR ADC, and comprises a precharge step of setting an initial state of binary-weighted capacitors configured in a first ADO channel and a second ADC channel, and a capacitance-calibration step of sequentially calibrating the binary-weighted capacitors of the first ADC channel and the second ADC channel by connecting the binary-weighted capacitors in a parallel connection or an antiparallel connection.

This application claims priority to Korean Patent Application No. 10-2024-0178780 filed on Dec. 4, 2024, in the Korean Intellectual Property Office (KIPO), the entire contents of which are incorporated herein by reference.

### BACKGROUND

### 1. Field of the Invention

The present invention relates to a foreground self-calibration method for a split successive-approximation register analog-to-digital converter and an apparatus thereof, and more specifically, to an efficient foreground self-calibration method of restoring a binary-weighted relationship between capacitors through a designed platform so as to improve overall linearity and performance of a successive-approximation register analog-to-digital converter (SAR ADC).

### 2. Description of the Related Art

Capacitor mismatch caused by various defects due to variations in the manufacturing process significantly affects the linearity of the capacitor array used in implementing a capacitive digital-to-analog converter (CDAC) of a successive-approximation register (SAR) analog-to-digital converter (ADC). Accordingly, the linearity of the SAR ADC is limited by the capacitor array, leading to severe yield losses.

In a conventional split ADC shown in FIG. 1, the ADC input signal Vin is simultaneously applied to two identical ADCs, namely ADC 1 and ADC 2. Their outputs x₁ and x₂ are provided to respective bit-weighting functions f_{w1} and f_{w2} to be multiplied by weights w₁ and w₂. The ADC outputs d₁ and d₂ are averaged in an output processing module to produce do, which is used as a normal operation output, while an output difference dₑ=d₂−d₁, representing an error between the two ADCs, is applied to a weight-update module.

As shown in [Equation 1] below, an adaptive algorithm such as least mean square (LMS) updates w₁ and w₂ in the weight-update module on the basis of dₑ.

$${w}_{1} ( n + 1 ) = {w}_{1} ( n ) - μ {d}_{e} ( n ) {x}_{1} ( n ) \qquad [ Equation 1 ]$$

$${w}_{2} ( n + 1 ) = {w}_{2} ( n ) - μ {d}_{e} ( n ) {x}_{2} ( n )$$

Here, n represents the sample index, and u represents the LMS step size. w₁ and w₂ are then appropriately multiplied with the next outputs x₁ and x₂ in f_{w1} and f_{w2}, respectively. This process is repeated until d₁ becomes equal to d₂.

Some advantages of the split ADC architecture may be described as follows. Since each ADC channel occupies half of the original ADC area, the split ADC does not require a larger area. Furthermore, each channel occupies half of the capacitance used by the original ADC, allowing noise at the output to be reduced by the averaging process.

However, when the two channel outputs have the same polarity and contain similar errors, the output difference may not adequately reflect the mismatch between the two ADC channels. Consequently, [Equation 1] results in [Equation 2], and the bit weights are not updated, masking the mismatch and reducing calibration accuracy.

$${w}_{1} ( n + 1 ) \approx {w}_{1} ( n ) \qquad [ Equation 2 ]$$

$${w}_{2} ( n + 1 ) \approx {w}_{2} ( n )$$

### SUMMARY

An object of the present invention is to propose an efficient foreground self-calibration technique that alleviates nonlinearity caused by capacitor mismatch in the SAR ADC and thus improves performance.

However, the technical problems to be solved by the present invention are not limited to the above problems, and may be variously extended within a scope that does not depart from the technical spirit and scope of the present invention.

According to an embodiment of the present invention, a foreground self-calibration method for a split successive-approximation register analog-to-digital converter (SAR ADC) comprising at least one processor comprises a precharge step of setting an initial state of binary-weighted capacitors configured in a first ADC channel and a second ADC channel, and a capacitance-calibration step of sequentially calibrating the binary-weighted capacitors of the first ADC channel and the second ADC channel by connecting the binary-weighted capacitors in a parallel connection or an antiparallel connection.

According to an embodiment of the present invention, a foreground self-calibration apparatus for a split successive-approximation register analog-to-digital converter (SAR ADC) comprises a precharge unit configured to set an initial state of binary-weighted capacitors configured in a first ADC channel and a second ADC channel, and a capacitance-calibration unit configured to sequentially calibrate the binary-weighted capacitors of the first ADC channel and the second ADC channel by connecting the binary-weighted capacitors in a parallel connection or an antiparallel connection.

According to an embodiment of the present invention, by proposing a foreground self-calibration method that alleviates nonlinearity caused by capacitor mismatch in SAR ADC and improves performance, an influence of capacitor mismatch due to due to variations in the manufacturing process on linearity of the SAR ADC may be reduced.

According to an embodiment of the present invention, unlike conventional method, an adaptive algorithms (e.g., LMS algorithm) are not required, thereby reducing hardware complexity, and more efficient calibration may be achieved by utilizing 2-ADC channels (first ADC channel and second ADC channel).

However, the effects of the present invention are not limited to the above effects, and may be variously extended within a scope that does not depart from the technical spirit and scope of the present invention.

### BRIEF DESCRIPTION OF THE DRAWINGS

FIG. 1 shows a configuration of a conventional split ADC.

FIGS. 2A and 2B show each flowchart of an operation of a foreground self-calibration method according to an embodiment of the present invention.

FIG. 3 shows a block diagram illustrating detailed configurations of a foreground self-calibration apparatus according to an embodiment of the present invention.

FIGS. 4A to 4C show each a configuration of a foreground self-calibration technique according to an embodiment of the present invention.

FIGS. 5A to 5C show each circuit diagram illustrating symbols of variable capacitors and binary-weighted capacitors according to an embodiment of the present invention.

FIG. 6 shows a circuit diagram illustrating a precharge step according to an embodiment of the present invention.

FIG. 7 shows a circuit diagram illustrating the capacitance calibration step according to an embodiment of the present invention.

FIG. 8 shows a table illustrating capacitors used in each calibration step.

FIG. 9A to 9C show each circuit diagram illustrating the connection for the para-switch according to an embodiment of the present invention.

FIG. 10 shows a diagram illustrating switch values for a calibration mode and a normal mode according to an embodiment of the present invention.

FIGS. 11A and 11B show each diagram illustrating correlations between various parameters for a flowchart of the foreground self-calibration technique according to an embodiment of the present invention.

FIGS. 12A to 12C show each circuit diagram illustrating connections of para-switches entering a calibration mode according to an embodiment of the present invention.

FIGS. 13A and 13B show each graph illustrating the results of the DNL and INL plots measured before and after applying the foreground self-calibration technique proposed in the present invention.

FIG. 14 shows a graph illustrating the spectrum response results measured before and after applying the foreground self-calibration technique proposed in the present invention.

### DETAILED DESCRIPTION

The advantages and features of the present invention, and the methods of achieving them, will become apparent by reference to the embodiments described in detail hereinafter in conjunction with the accompanying drawings. However, the present invention is not limited to the embodiments disclosed below but will be implemented in various different forms, and these embodiments are provided only to make the disclosure of the present invention complete and to fully inform those skilled in the art to which the present invention belongs of the scope of the invention, and the present invention is defined only by the scope of the claims.

The terms used in this specification are for describing the embodiments and are not intended to limit the present invention. As used herein, the singular forms also include the plural forms unless specifically stated otherwise in the context. The terms “comprises” and/or “comprising”, as used in herein, do not exclude the presence or addition of one or more other components, steps, operations, and/or elements in addition to the stated components, steps, operations, and/or elements.

Unless otherwise defined, all terms (including technical and scientific terms) used in herein may have meanings commonly understood by a person having ordinary skill in the art to which the present invention pertains. Also, terms defined in commonly used dictionaries are not to be interpreted ideally or excessively unless clearly specifically defined.

Hereinafter, preferred embodiments of the present invention will be described in more detail with reference to the accompanying drawings. The same reference numerals are used for the same components in the drawings, and redundant descriptions of the same components are omitted.

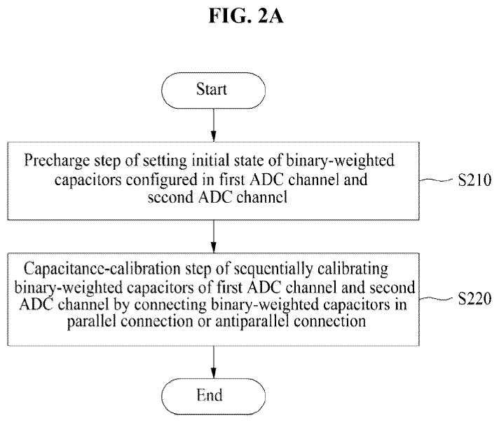

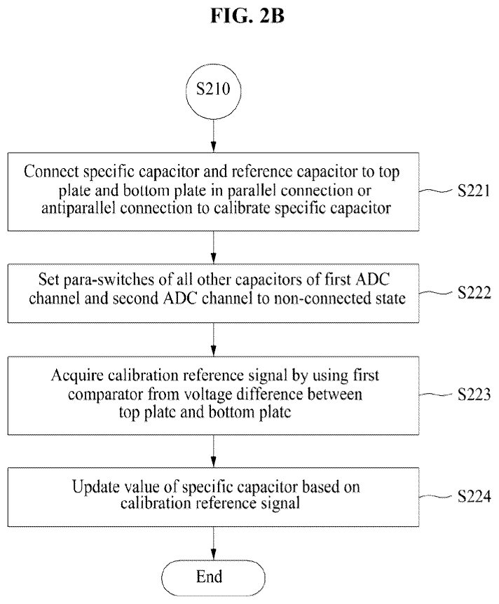

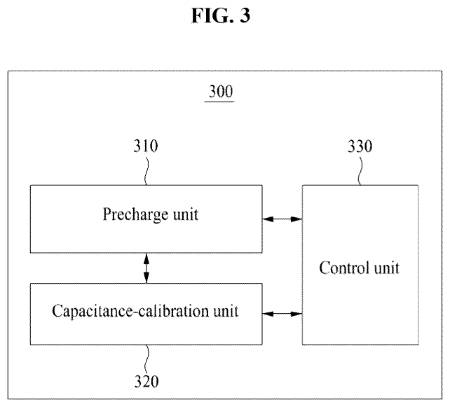

FIGS. 2A and 2B show each flowchart of an operation of a foreground self-calibration method according to an embodiment of the present invention, and FIG. 3 shows a block diagram illustrating detailed configurations of a foreground self-calibration apparatus according to an embodiment of the present invention.

The method of FIG. 2a and FIG. 2b is performed by a foreground self-calibration apparatus 300 according to an embodiment of the present invention shown in FIG. 3.

The steps shown in FIGS. 2a and 2b (S210 to S224) are performed by a precharge unit 310 and a capacitance-calibration unit 320 that constitute the foreground self-calibration apparatus 300 according to an embodiment of the present invention shown in FIG. 3.

Referring to FIGS. 2A, 2B, and 3, in step S210, the precharge unit 310 sets an initial state of binary-weighted capacitors configured in a first ADC channel and a second ADC channel.

The precharge unit 310 deactivates a first comparator (comp 1) and a second comparator (comp 2) by connecting para-switches of all binary-weighted capacitors of the first ADC channel and the second ADC channel in a parallel connection, and may precharge all of the binary-weighted capacitors by a reference voltage (V_{REF}).

At this time, the first ADC channel and the second ADC channel are configured as successive-approximation register analog-to-digital converters (SAR ADCs), and the successive-approximation register analog-to-digital converters (SAR ADCs) have a differential input structure and may utilize average between outputs of the first ADC channel and the second ADC channel. The first ADC channel and the second ADC channel may include a capacitive digital-to-analog converter (CDAC) comprising a binary-weighted capacitor array configured as variable capacitors.

In step S220, the capacitance-calibration unit 320 sequentially calibrates the binary-weighted capacitors of the first ADC channel and the second ADC channel by connecting the binary-weighted capacitors in the parallel connection or antiparallel connection.

The capacitance-calibration unit 320 may sequentially calibrate all binary-weighted capacitors in the first ADC channel and the second ADC channel from a least significant bit (LSB) capacitor to a most significant bit (MSB) capacitor so as to construct binary-weighted relationships of all capacitors.

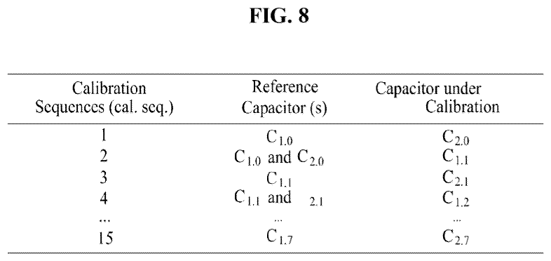

The capacitance-calibration unit 320 uses one reference capacitor of the first ADC channel to calibrate one specific capacitor of the second ADC channel in odd-numbered calibration sequences, and uses two reference capacitors from the first ADC channel and the second ADC channel to calibrate one specific capacitor of the first ADC channel in even-numbered calibration sequences. More specifically, in odd-numbered calibration sequences such as the first, third, and fifth calibration sequences shown in FIG. 8, one reference capacitor of the first ADC channel may be used to calibrate one specific capacitor of the second ADC channel. In addition, in even-numbered calibration sequences such as the second, fourth, and sixth calibration sequences shown in FIG. 8, two reference capacitors respectively from the first ADC channel and the second ADC channel may be used to calibrate one specific capacitor of the first ADC channel. Accordingly, the capacitance-calibration unit 320 updates all capacitances so as to satisfy a binary-weighted relationship (Cₙ=2×Cₙ₋₁) by using only one or two reference capacitors.

In step S221, the capacitance-calibration unit 320 may connect a specific capacitor and a reference capacitor to a top plate and a bottom plate in the parallel connection or antiparallel connection to calibrate the specific capacitor. More specifically, in order to calibrate a specific capacitor Cₙ of the first ADC channel, the capacitance-calibration unit 320 may connect para-switches within two reference capacitors Cₙ₋₁ from the first ADC channel and the second ADC channel to the top plate and the bottom plate in the parallel connection (S_{para.ch.x}) or the antiparallel connection (S_{anti.ch.x}).

In step S222, the capacitance-calibration unit 320 sets para-switches of all other capacitors from the first ADC channel and the second ADC channel to a non-connected state so as to disconnect the top plate and the bottom plate. Accordingly, a second comparator is deactivated, and a first comparator may be activated.

In step S223, the capacitance-calibration unit 320 may acquire a calibration reference signal from a voltage difference between the top plate and the bottom plate by using the first comparator. More specifically, the capacitance-calibration unit 320 may acquire a calibration reference signal (v_{cal}) by using the first comparator to calculate a voltage difference between the specific capacitor Cₙ and a sum of two reference capacitors Cₙ₋₁ from the first ADC channel and the second ADC channel.

In step S224, the capacitance-calibration unit 320 may update a value of the specific capacitor Cₙ based on the calibration reference signal. At this time, the capacitance-calibration unit 320 acquires a specific capacitor that satisfies the condition that the calibration reference signal becomes zero, and updates a value of the acquired specific capacitor.

The capacitance-calibration unit 320 repeatedly performs the process until the specific capacitor Cₙ of the first ADC channel and the second ADC channel satisfies the binary-weighted relationship (Cₙ=2×Cₙ₋₁) corresponding to a sum of the two reference capacitors Cₙ₋₁.

The foreground self-calibration method and apparatus thereof according to an embodiment of the present invention may further include a control unit 330 configured to perform a step (not shown) of switching between a normal mode and a calibration mode.

The control unit 330 performs steps S210 and S220 in the calibration mode through the precharge unit 310 and the capacitance-calibration unit 320, and may convert data in a state in which calibration has been completed in the normal mode. In the present invention, the normal mode is a mode that performs a function of converting an input signal into a digital value and outputting the digital value, and the calibration mode is a mode that performs self-calibration to reduce capacitor mismatch or signal distortion. Accordingly, the foreground self-calibration method and apparatus thereof according to an embodiment of the present invention may secure accuracy and stability of signals by utilizing both the normal mode and the calibration mode.

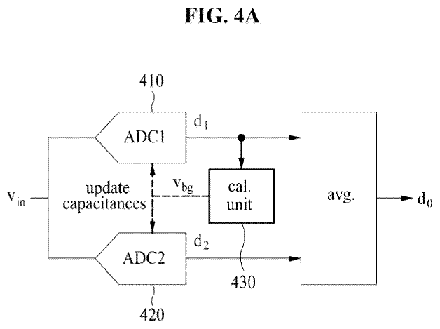

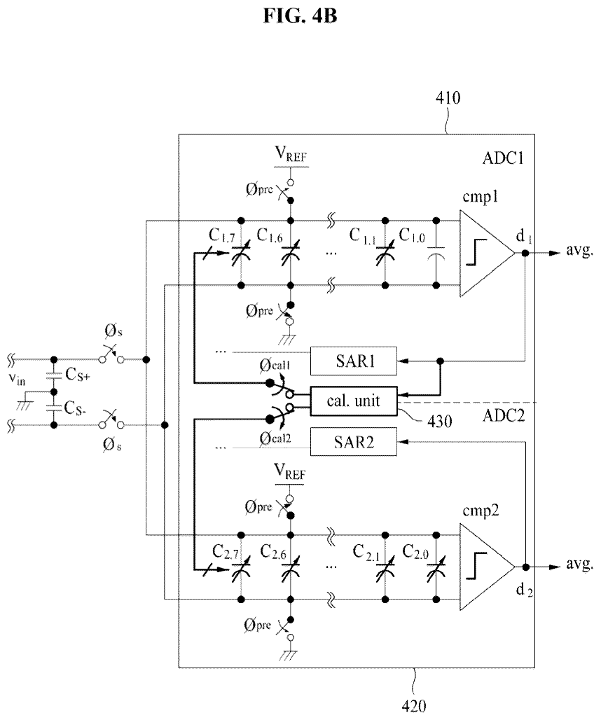

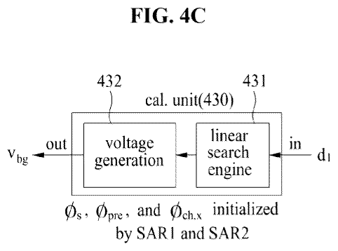

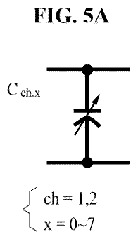

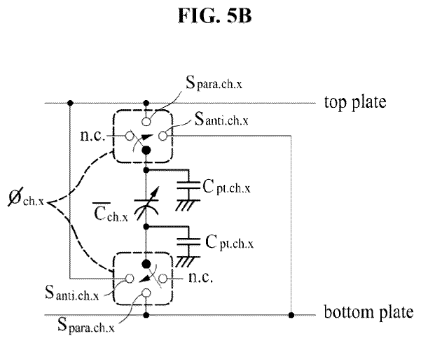

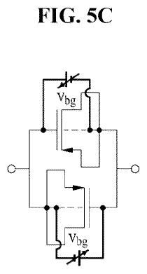

FIGS. 4A to 4B show each a configuration of a foreground self-calibration technique according to an embodiment of the present invention, and FIGS. 5A to 5C show each circuit diagram illustrating symbols of variable capacitors and binary-weighted capacitors according to an embodiment of the present invention.

More specifically, FIG. 4A shows a configuration diagram of the foreground self-calibration technology according to an embodiment of the present invention, FIG. 4B shows a circuit diagram of the proposed foreground self-calibration based on a split CS-SAR ADC, and FIG. 4C shows a configuration diagram of a calibration unit embedded in FIG. 4B. In addition, FIG. 5A shows symbols of variable capacitors and binary-weighted capacitors used in FIG. 4B, FIG. 5B shows a circuit diagram of a capacitor with a para-switch in FIG. 5A, and FIG. 5C shows a circuit diagram that may be implemented using a variable MOSCAP.

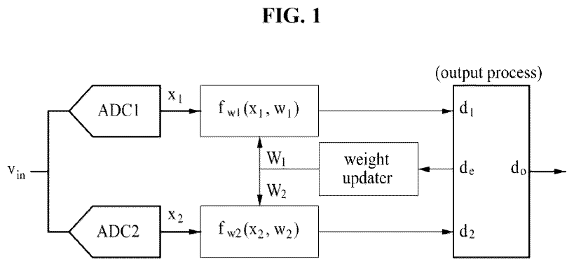

The foreground self-calibration technique according to an embodiment of the present invention is derived from FIG. 1, and may be simply configured by using a split ADC platform as shown in FIG. 4A. The adaptive algorithm using two ADC channels (ADC 1 and ADC 2) and the dₑ basically required in the output averaging process in the conventional split ADC shown in FIG. 1 is not required in the foreground self-calibration technique according to the embodiment of the present invention. Accordingly, the foreground self-calibration technique proposed in the present invention uses two ADC channels (a first ADC channel 410 and a second ADC channel 420) for calibration purposes. These two ADC channels 410 and 420 provide an efficient platform for a calibration unit 430 to calibrate each capacitor using several reference capacitors, so a much simpler process may be created.

The binary-weighted capacitor in CDACs of each of the two ADC channels 410 and 420 are implemented by using MOSCAPs, which are a type of variable capacitor, wherein when a capacitance-control signal v_{bg} is applied to the MOSCAP, the MOSCAP is set to a corresponding capacitance. At this time, the capacitance of the MOSCAP becomes lower as a value of v_{bg} becomes higher. Basically, a MOSCAP is a voltage-controlled variable capacitor. As shown in FIG. 4C, the calibration unit 430 consists of two processes: a linear search process 431 for calibration for applying the aforementioned v_{bg} to the MOSCAP, and voltage generation 432 (by an internal voltage generator). This operation is not limited to a specific architecture of a voltage generation circuit as long as an accurate v_{bg} value may be generated.

To better understand this concept, an 8-bit ADC is used as an example, and the proposed operation may be simply applied to higher resolutions of the ADC.

The proposed operation of FIG. 4A may be implemented as shown in FIG. 4B. A charge-sharing (CS) SAR ADC with a differential input is used for both the first ADC channel 410 and the second ADC channel 420, and each step consists of a track/hold step (omitted for simplification in FIG. 4B), a sampling step (Cₛ₊ and Cₛ₋), a CDAC (C_{ch.x}), and a comparator (comp1 or comp2).

The notation C_{ch.x} of the CDAC represents a binary-weighted capacitor or a capacitance of the context, wherein the subscript ch represents an index (e.g., 1 or 2) of each ADC channel 410 and 420, and the other subscript x represents an index of each capacitor in the CDAC (e.g., 0-7 for an 8-bit ADC). Thus, ideally, C_{1.7}=C_{2.7}=2⁷Cu, C_{1.6}=C_{2.6}=2⁶Cu, . . . , C_{1.0}=C_{2.0}=Cu, where Cu represents a unit capacitor. In addition, φₚᵣₑ is kept open so as to connect between the top plate and the bottom plate of the first ADC channel 410. Each binary-weighted capacitor of a conventional CS-SAR ADC includes two internal switches φ_{ch.x} for each C_{ch.x}, as shown in FIGS. 5A and 5B. As shown in FIG. 5B, each C_{ch.x} may be connected to the top plate or the bottom plate through these two switches, thereby enabling a parallel connection (S_{para.ch.x}) or an antiparallel connection (S_{anti.ch.x}) of C_{ch.x}. For convenience, these two switches are referred to as φ_{ch.x}, para-switches. In addition, an actual capacitance C_{ch.x} may be modeled as a capacitance combined with an ideal capacitance C̅_{ch.x}, which is parasitic capacitance occurring at the top plate and the bottom plate, respectively.

Various types of capacitors may be considered for use in a CDAC. A metal-oxide-metal (MOM) capacitor has good linearity but exhibits a low capacitance density due to thick oxide layers. In addition, metal-insulation-metal (MIM) and poly-insulation-poly (PIP) capacitors exhibit excellent linearity and high capacitance density due to thin oxide layers, but require additional masks and more manufacturing steps, thereby increasing manufacturing cost. In contrast, MOSCAPs do not require an additional mask process because it has a high capacitance density. Regarding the structure of MOSCAPs, as shown in FIG. 50, capacitance is introduced between a bulk and a gate of a metal-oxide-semiconductor field-effect transistor (MOSFET), and the gate and source (connected to a drain) are the two terminals of the variable MOSCAP. Then, by increasing the input voltage v_{bg} between the bulk and gate, a capacitance between the two terminals decreases almost linearly, thereby creating the MOSCAP as a variable capacitor. However, these capacitors suffer from nonlinearity, and MOSCAPs have capacitance that varies according to the voltage value across the entire MOSCAP in the depletion region, while remaining generally constant in the accumulation and inversion regions. Conventional techniques use MOSCAPs in the inversion region and replace all capacitors of the CDAC with variable MOSCAPs as shown in FIG. 5C, thereby calibrating the SAR ADC based on binary-weighted relationships between capacitors along with dummy unit capacitors according to calibration purposes.

The foreground self-calibration technique according to embodiments of the present invention fully charges the conventionally used variable MOSCAP in the precharge step. Then, since the passive CDAC of the CS SAR ADC is not connected to power supply and is also not connected to external circuits (assuming high impedance at the input terminal of a comparator), a net amount of charge of the a capacitor is maintained identical until the sampling step is completed. Accordingly, the MOSCAP is kept in the inversion region during a calibration process. An objective of the calibration technique proposed in the present invention is to overcome disadvantages of a conventional split ADC and to achieve a highly accurate calibration methodology by using a conventionally used variable capacitor and an input voltage generator. In addition, a variable capacitor used in a calculation device may be not only a capacitor array but also a voltage-controlled capacitor (e.g., variable MOSCAPs, varactors, etc.). In practice, proposing a new variable capacitor together with an input voltage generator is not trivial and thus is beyond the scope of the calibration technique proposed in the present invention.

Accordingly, the foreground self-calibration technique according to an embodiment of the present invention is highlighted, in FIG. 4B, by a variable-capacitor-based array of the CDAC, a node Stop/bow, a calibration unit 430, and switches φ_{cal1/2}. In addition, for efficiency, a set of track/hold steps and a set of sample steps, which are designed for each of two ADC channels of a conventional split ADC, are merged into one set so that the two ADC channels 410 and 420 may share the proposed calibration technique of the present invention as shown in FIG. 4B.

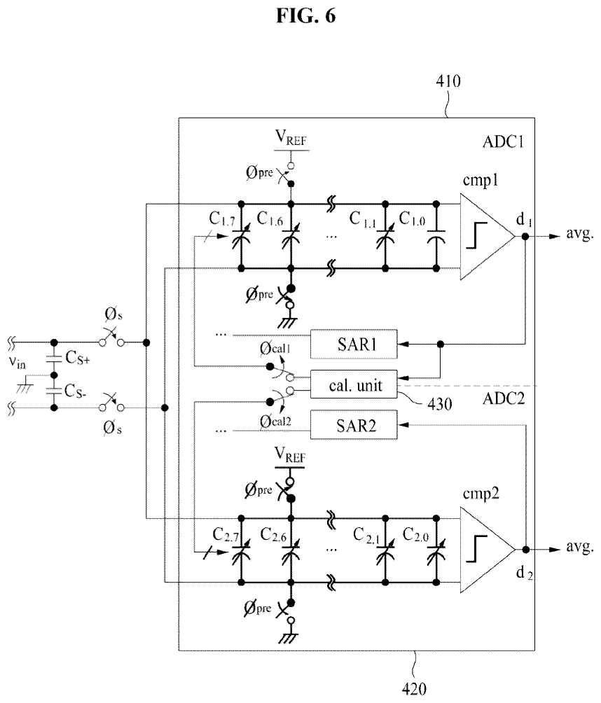

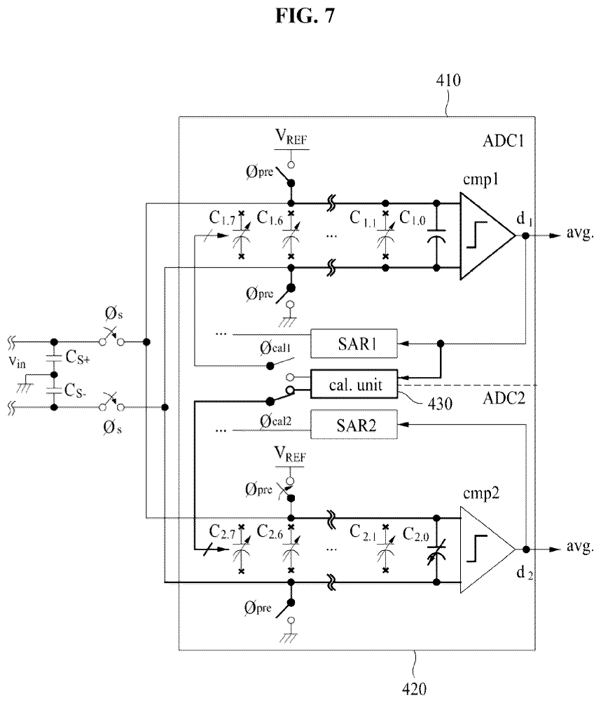

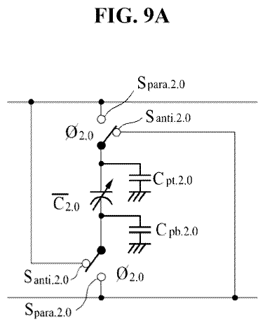

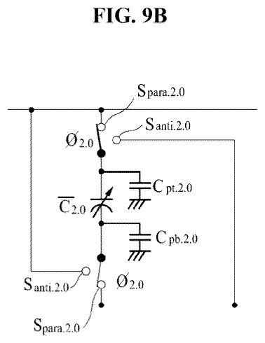

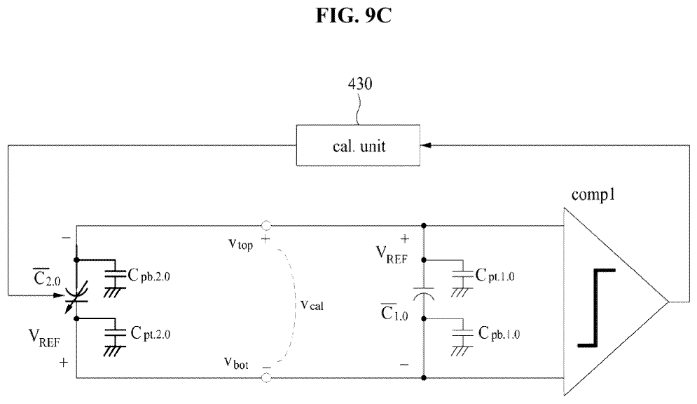

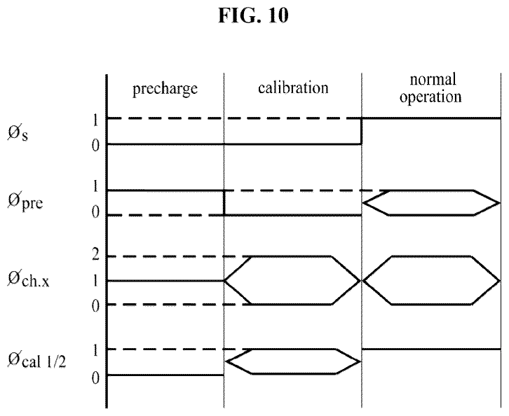

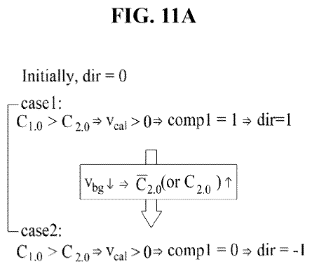

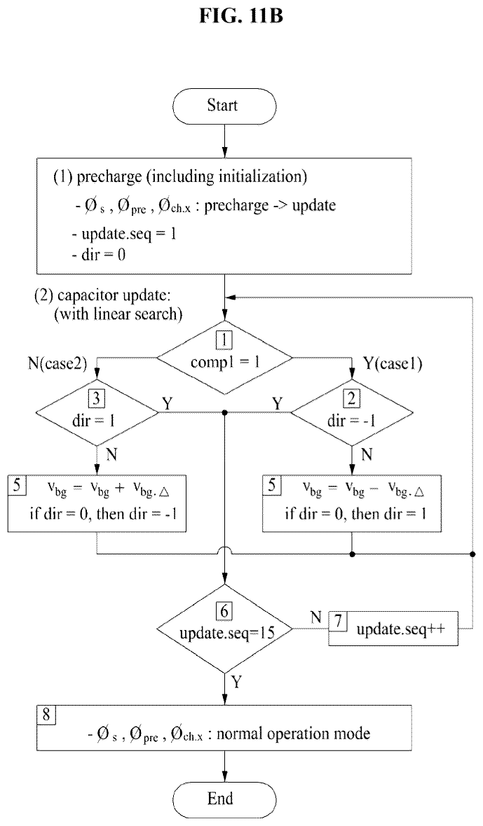

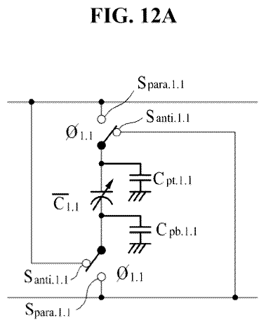

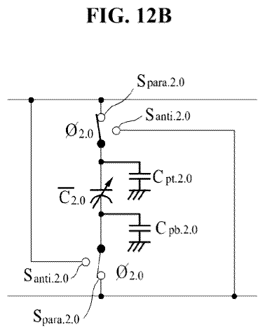

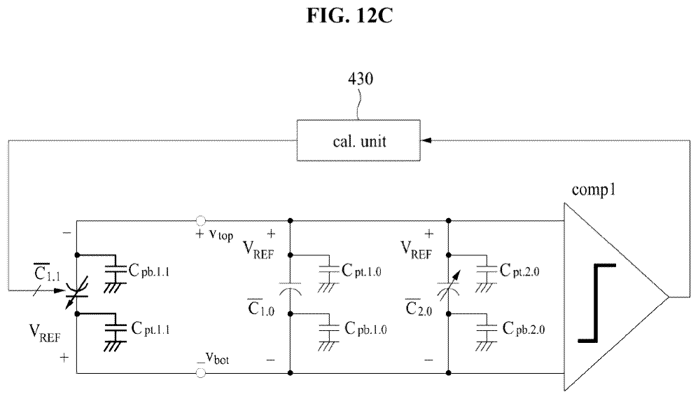

FIG. 6 shows a circuit diagram illustrating a precharge step according to an embodiment of the present invention, FIG. 7 shows a circuit diagram illustrating the capacitance calibration step according to an embodiment of the present invention, FIG. 8 shows a table illustrating capacitors used in each calibration step, and FIG. 9A to 9C show each circuit diagram illustrating the connection for the para-switch according to an embodiment of the present invention. Furthermore, FIG. 10 shows a diagram illustrating switch values for a calibration mode and a normal mode according to an embodiment of the present invention, FIGS. 11A and 11B show each diagram illustrating correlations between various parameters for a flowchart of the foreground self-calibration technique according to an embodiment of the present invention, and FIGS. 12A to 12C show each circuit diagram illustrating connections of para-switches entering a calibration mode according to an embodiment of the present invention.

The foreground self-calibration technique according to an embodiment of the present invention is performed in a precharge step and a capacitance-calibration step, and the entire process operates as a calibration unit.

For the precharge step (step S210), the split CS-SAR ADC shown in FIG. 4B is reconfigured as shown in FIG. 6 by performing the following: φₛ may disconnect a sampling step (i.e., Cₛ₊ and Cₛ₋) from the CDAC for two channels 410 and 420; φₚᵣₑ is closed so as to provide charge to all binary-weighted capacitors; then, para-switches of all capacitors are connected to S_{para.ch.x} as shown in FIG. 5B, comp1 (first comparator) and comp2 (second comparator) are deactivated, and finally all binary-weighted capacitors are fully precharged by V_{REF}.

For the capacitance-calibration step (step S220), binary-weighted capacitors are sequentially calibrated from the least significant bit (LSB) capacitor to the most significant bit (MSB) capacitor so as to complete all capacitors of a binary-weighted relationship.

More specifically, a first calibration sequence of FIG. 8 calibrates C_{2.0} (a specific capacitor) is calibrated by using C_{1.0} as a reference capacitor without change of C_{1.0} after fabrication, as shown in FIG. 7. First, an LSB capacitor (i.e., C_{1.0} and C_{2.0}) of each ADC channel is connected to the top plate and the bottom plate in the antiparallel connection. For this purpose, φ_{2.0} is set to S_{anti.2.0} as shown in FIG. 9A, and φ_{1.0} is set to S_{para.1.0} as shown in FIG. 9B. On the other hand, all other capacitors disconnect from the top plate and bottom plate by setting para-switches to n.c. (i.e., non-connected). In addition, assuming that a common-mode voltage is ignored for simplicity, comp2 (second comparator) is deactivated and comp1 (first comparator) is activated. Basically, φₚᵣₑ is opened in both ADC channels 410 and 420 in FIG. 7 to connect C_{2.0} of the second ADC channel 420 to C_{1.0} and comp1. Accordingly, values of switches for a calibration mode and a normal mode proposed in the present invention are summarized in FIG. 10. For better explanation, only the effective circuit is shown in FIG. 9C.

In FIG. 9C, a voltage v_{cal} between the top plate and the bottom plate is derived by charge conservation from [Equation 3] to [Equation 7] below. Despite the moment when C_{1.0} and C_{2.0} are initially connected in antiparallel connection (i.e., time immediately after the precharge step, t=0), V_{REF} Still drops across each capacitor. As described in FIG. 5B, C_{pt.1.0} and C_{pb.1.0} are parasitic capacitances of C̅_{1.0}, and C_{pt.2.0} and C_{pb.2.0} are parasitic capacitances of C̅_{2.0} as modeled in the prior art. Then, a total initial charge Q_{ini.top} at the top plate of FIG. 9C may be identified as follows:

$${Q}_{ini . top \text{.1} \text{.0}} = {\overline{C}}_{1.} ( {V}_{REF} - 0 ) + {C}_{pt \text{.1} \text{.0}} ( {V}_{REF} - 0 ) \qquad [ Equation 3 ]$$

$${Q}_{ini . bot \text{.2} \text{.0}} = {\overline{C}}_{2.} ( 0 - {V}_{REF} ) + {C}_{pb \text{.2} \text{.0}} ( 0 - 0 )$$

$$\begin{matrix}{Q}_{ini . top} = {Q}_{ini . top \text{.1} \text{.0}} + {Q}_{ini . bot \text{.2} \text{.0}} \\ = ( {\overline{C}}_{1.} + {C}_{pt \text{.1} \text{.0}} - {\overline{C}}_{2.} ) {V}_{REF}\end{matrix}$$

Here, Q_{ini.top.1.0} and Q_{ini.bot.2.0} represent the initial charges of the top plate of C̅_{1.0} and the bottom plate of C̅_{2.0} made in the precharge step, respectively. Therefore, Q_{ini.top} represents a sum of these charges in an antiparallel connection circuit. Similarly, the total initial charge Q_{ini.bot} of bottom plate of the CDAC may be obtained as follows:

$${Q}_{ini . bot \text{.1} \text{.0}} = {\overline{C}}_{1.} ( 0 - {V}_{REF} ) + {C}_{pb \text{.1} \text{.0}} ( 0 - 0 ) \qquad [ Equation 4 ]$$

$${Q}_{ini . top \text{.2} \text{.0}} = {\overline{C}}_{2.} ( {V}_{REF} - 0 ) + {C}_{pt \text{.2} \text{.0}} ( {V}_{REF} - 0 )$$

$$\begin{matrix}{Q}_{ini . bot} = {Q}_{ini . bot \text{.1} \text{.0}} + {Q}_{ini . top \text{.2} \text{.0}} \\ = ( {\overline{C}}_{2.} + {C}_{pt \text{.2} \text{.0}} - {\overline{C}}_{1.} ) {V}_{REF}\end{matrix}$$

Here, Q_{ini.bot.1.0} and Q_{ini.top.2.0} represent the initial charges of the bottom plate of C̅_{1.0} and the top plate of C̅_{2.0}, respectively. Similarly, in the antiparallel connection circuit, Q_{ini.bot} represents the sum of these charges.

On the other hand, when t>0, the total final charges Q_{fin.top} and Q_{fin.bot} of the top plate and bottom plate may be obtained as follows:

$${Q}_{fin . top} = ( {C}_{pt \text{.1} \text{.0}} + {C}_{pb \text{.2} \text{.0}} ) {v}_{top} + ( {\overline{C}}_{1.} + {\overline{C}}_{2.} ) ( {v}_{top} - {v}_{bot} ) \qquad [ Equation 5 ]$$

$${Q}_{fin . bot} = ( {C}_{pb \text{.1} \text{.0}} + {C}_{pt \text{.2} \text{.0}} ) {v}_{bot} + ( {\overline{C}}_{1.} + {\overline{C}}_{2.} ) ( {v}_{bot} - {v}_{top} )$$

Here, vₜₒₚ and v_{bot} represent the voltages of the top plate and bottom plate of the CDAC, respectively, and are also defined as v_{cal}=vₜₒₚ−v_{bot}, which is the input voltage of comp1.

Then, through charge conservation, two relationships Q_{ini.top}=Q_{fin.top} and Q_{ini.bot}=Q_{fin.bot} are obtained, which may be described using [equation 3], [equation 4] and [equation 5]:

$$( {\overline{C}}_{1.} + {C}_{pt \text{.1} \text{.0}} - {\overline{C}}_{2.} ) {V}_{REF} = ( {C}_{pt \text{.1} \text{.0}} + {C}_{pb \text{.2} \text{.0}} ) {v}_{top} + ( {\overline{C}}_{1.} + {\overline{C}}_{2.} ) ( {v}_{top} - {v}_{bot} ) \qquad [ Equation 6 ]$$

$$( {\overline{C}}_{2.} + {C}_{pt \text{.2} \text{.0}} - {\overline{C}}_{1.} ) {V}_{REF} = ( {C}_{pb \text{.1} \text{.0}} + {C}_{pt \text{.2} \text{.0}} ) {v}_{bot} + ( {\overline{C}}_{1.} + {\overline{C}}_{2.} ) ( {v}_{bot} - {v}_{top} )$$

Here, v_{cal} may be finally obtained by solving a system of equations in [Equation 6] as follows:

$${v}_{cal} = \frac{\begin{matrix}{C}_{pt \text{.1} \text{.0}} {C}_{pb \text{.1} \text{.0}} - {C}_{pt \text{.2} \text{.0}} {C}_{pb \text{.2} \text{.0}} + \\ ( {C}_{pt \text{.1} \text{.0}} + {C}_{pt \text{.2} \text{.0}} + {C}_{pb \text{.1} \text{.0}} + {C}_{pb \text{.2} \text{.0}} ) {\hat{C}}_{1}\end{matrix}}{( {C}_{pt \text{.1} \text{.0}} + {C}_{pt \text{.1} \text{.0}} ) {\check{C}}_{1} + {C}_{pt \text{.1} \text{.0}} + {\hat{C}}_{1} ) ( {C}_{pb \text{.1} \text{.0}} + {C}_{pt \text{.2} \text{.0}} )} \times {v}_{top} \qquad [ Equation 7 ]$$

Here, Č₁=C̅_{1.0}+C̅_{2.0} and Ĉ₁=C̅_{1.0}−C̅_{2.0}. A comparison technique using antiparallel connections between multiple capacitors has been used in conventional CS-SAR ADC.

As can be seen in [Equation 7], v_{cal} represents a function of C̅_{2.0} as a variable capacitance. The proposed calibration algorithm based on the correlation of [Equation 7] is briefly summarized in FIG. 11A. Here, C_{1.0}>C_{2.0} and v_{cal}>0, so if the output of comp1 is 1, this condition is defined as case1 using the case indicator dir=1. After that, v_{bg} decreases so that C_{2.0} increases, and the moment when C_{1.0}<C_{2.0} Or v_{cal}<0 is defined as case2 and is indicated by using dir=−1. The linear search for the calibration of C_{2.0} is completed in the transition from case1 to case2, which may be considered as the moment when C_{1.0}≈C_{2.0} or v_{cal}≈0. The linear search also operates similarly in the reverse transition from case2 to case1. Overall, the calibration process for each capacitor being calibrated is completed at the transition (dir=0) between case1 (dir=1) and case2 (dir=−1). For the circuit process, the linear search engine 431 and the voltage generation circuit of the calibration unit 430 are used to search for an appropriate v_{bg} value to make the two voltages charged at C_{1.0} and C_{2.0} equal, and if C_{1.0}>C_{2.0}, which may be expected using comp1 output, d1=1, the voltage generation circuit provides an increased v_{bg} lower than C_{1.0}, and vice versa.

A flowchart of the calibration technique proposed in the present invention based on [Equation 7] and FIG. 11A is illustrated in FIG. 11B. A process of the flowchart is performed to calibrate the capacitance, i.e., a second step of the calibration technique proposed in the present invention. All of these procedures are controlled by the linear search engine 431 of the cal unit 430 shown in FIG. 4C. Initially, dir=0 immediately after the precharge step is completed. Numbers from #1 to #8 are entered for each flow in FIG. 11B. At #1, v_{cal} of [Equation 7] is measured with comp1, then it is asked whether comp1 output=1 or case1 (i.e., C_{1.0}>C_{2.0} and v_{cal}>0), and whether the current dir=−1 of #2 previously belonged to case2 or is at the transition between case1 and case2. Since dir=0 initially, it goes to #4. dir becomes 1, indicating case1. In addition, v_{bg} decreases by the step size v_{bg.Δ} of the MOSCAP to update C̅_{2.0}. Then, since v_{cal} correlates with the updated C_{2.0} as in [Equation 7], after v_{cal} is measured again, it returns to #1 to check if comp1 output=1. If comp1 output=0 at this time, it moves to #3, which is case2. Since it was previously case1 and currently dir=1, this moment may be considered as the moment when case1 becomes C_{1.0}≈C_{2.0} Or v_{cal}≈0, so the linear search for the calibration of C_{2.0} is completed as confirmed earlier. C_{2.0} may correlate with parasitic capacitances C_{pt2.0} and C_{pt2.0}, and thus the correlated v_{bg} of [Equation 7] is confirmed to satisfy v_{cal}≈0 for the calibration of C_{2.0}. Then it moves to #6 to check if cal.seq=15 (i.e., the last calibration sequence in FIG. 8). If not, the second calibration sequence is set to #7 (i.e., cal.seq.=2), which will be described in detail below.

As in the general linear search method, the higher the process time and value of v_{bg.Δ} of the linear search, the faster the linear search may be performed and the lower the accuracy of the values retrieved, or vice versa. Also, from [Equation 7], to satisfy v_{cal}=0, the following relationship may be concluded:

$${\overline{C}}_{2.} = {\overline{C}}_{1.} + \frac{{C}_{pt \text{.1} \text{.0}} {C}_{pb \text{.1} \text{.0}} - {C}_{pt \text{.2} \text{.0}} {C}_{pb \text{.2} \text{.0}}}{{C}_{pt \text{.1} \text{.0}} + {C}_{pt \text{.2} \text{.0}} + {C}_{pb \text{.1} \text{.0}} + {C}_{pb \text{.2} \text{.0}}} \qquad [ Equation 8 ]$$

The second calibration sequence in FIG. 8 has been previously calibrated, so C_{1.1} is calibrated using the sum of C_{1.0} and C_{2.0}, which may be reused as reference capacitors as shown in FIG. 12, so that it may be reused as a reference capacitor. Similarly, φₚᵣₑ is also open. C_{1.0} and C_{1.1} of the first ADC channel 410, and C_{2.0} and C_{1.1}, are connected in an antiparallel connection to the top plate and the bottom plate by setting φ_{1.0} and φ_{2.0} to S_{para.1.0} and S_{para.2.0}, respectively, as shown in FIGS. 12A and 12B. C_{1.0} is connected to S_{para.1.0} (omitted) as shown in FIG. 9B. All other capacitors are disconnected from the top plate and bottom plate, and comp2 is deactivated while comp1 is activated. As a result, C_{1.1} is connected in the antiparallel connection to C_{1.0} and C_{2.0} as shown in FIG. 12C.

The v_{cal} of FIG. 12C may be obtained based on charge conservation as follows. When C_{1.1}, C_{1.0}, and C_{2.0} are initially connected in the antiparallel connection, V_{REF} still falls across each capacitor immediately after the precharge step. Accordingly, C_{pt/pb.1.1} and C_{pt/pb.2.0} are similarly modeled as parasitic capacitances of the top plate and bottom plate of C_{1.1} and C_{2.0}, respectively, as shown in FIGS. 12A to 12C. Then, in the antiparallel circuit of FIG. 12C, the total initial charges Q_{ini.top} and Q_{ini.bot} of the top plate and bottom plate may be identified as follows.

$${Q}_{ini . top} = {Q}_{ini . bot \text{.1} \text{.1}} + {Q}_{ini . top \text{.1} \text{.0}} + {Q}_{ini . top \text{.2} \text{.0}} = ( {\overline{C}}_{1.} + {C}_{pt \text{.1} \text{.0}} + {\overline{C}}_{2.} + {C}_{pt \text{.2} \text{.0}} - {\overline{C}}_{1.1} ) {V}_{REF} \qquad [ Equation 9 ]$$

$${Q}_{ini . bot} = {Q}_{ini . top \text{.1} \text{.1}} + {Q}_{ini . bot \text{.1} \text{.0}} + {Q}_{ini . bot \text{.2} \text{.0}} = ( {\overline{C}}_{1.1} + {C}_{pt \text{.1} \text{.1}} - ( {\overline{C}}_{1.} + {\overline{C}}_{2.} ) ) {V}_{REF}$$

Here, Q_{ini.bot.1.1}=−C̅_{1.1}V_{REF}, Q_{ini.top.1.0}=(C̅_{1.0}+C_{pt.1.0})V_{REF}, and Q_{ini.top.2.0}=(C̅_{2.0}+C_{pt.2.0})V_{REF}, Q_{ini.top.1.1}=(C̅_{1.1}+C_{pt.1.1})V_{REF}, Q_{ini.bot.1.0}=−C̅_{1.0}V_{REF}, Q_{ini.bot.2.0}=C̅_{2.0}V_{REF}. Q_{ini.top.1.1} and Q_{ini.bot.1.1} are initial charges for the top plate and bottom plate of C_{1.1}, respectively, and are performed at the precharge step. On the other hand, when t>0, the total final charges Q_{fin.top} and Q_{fin.bot} of the top plate and bottom plate may be obtained as follows:

$${Q}_{fin . top} = ( {C}_{pb \text{.1} \text{.1}} + {C}_{pt \text{.1} \text{.0}} + {C}_{pt \text{.2} \text{.0}} ) {v}_{top} + ( {\overline{C}}_{1.1} + {\overline{C}}_{1.} + {\overline{C}}_{2.} ) ( {v}_{top} - {v}_{bot} ) \qquad [ Equation 10 ]$$

$${Q}_{fin . bot} = ( {C}_{pt \text{.1} \text{.1}} + {C}_{pb \text{.1} \text{.0}} + {C}_{pb \text{.2} \text{.0}} ) {v}_{bot} + ( {\overline{C}}_{1.1} + {\overline{C}}_{1.} + {\overline{C}}_{2.} ) ( {v}_{bot} - {v}_{top} )$$

Then, through charge conservation, we obtained two relations, Q_{ini.top}=Q_{fin.top} and Q_{ini.bot}=Q_{fin.bot}, which may be described using [Equation 9] and [Equation 10]:

$$( {\hat{C}}_{2} + {C}_{pt \text{.1} \text{.0}} + {C}_{pt \text{.2} \text{.0}} ) {V}_{REF} = {\check{C}}_{pb} {v}_{top} + {\check{C}}_{2} ( {v}_{top} - {v}_{bot} ) \qquad [ Equation 11 ]$$

$$( {C}_{pt \text{.1} \text{.1}} - {\hat{C}}_{2} ) {V}_{REF} = {\check{C}}_{pt} {v}_{bot} + {\check{C}}_{2} ( {v}_{bot} - {v}_{top} )$$

Here, Č₂=C̅_{1.0}+C̅_{2.0}+C̅_{1.1}, Č₂=C̅_{1.0}+C̅_{2.0}−C̅_{1.1}, Č_{pb}=C_{pb.1.1}+C_{pt.1.0}+C_{pt.2.0}, and Čₚₜ=C_{pt.1.1}+C_{pb.1.0}+C_{pb.2.0}. Finally, v_{cal} may be obtained by solving a system of equations in [Equation 11] as follows:

$${v}_{cal} = \frac{( {\hat{C}}_{2} + {C}_{pt \text{.1} \text{.0}} + {C}_{pt \text{.2} \text{.0}} ) {\check{C}}_{pt} - {\check{C}}_{pb} ( {C}_{pt \text{.1} \text{.1}} - {\hat{C}}_{2} ) {v}_{top}}{( {\hat{C}}_{2} + {C}_{pt \text{.1} \text{.0}} + {C}_{pt \text{.2} \text{.0}} ) ( {\check{C}}_{2} + {\check{C}}_{pt} ) + {\check{C}}_{2} ( {C}_{pt \text{.1} \text{.1}} - {\hat{C}}_{2} )} \qquad [ Equation 12 ]$$

As in the previous example, the linear search engine 431 of the cal unit (calibration unit) 430 finds C_{1.1} that satisfies v_{cal}≈0 in [Equation 12]. The flowchart in FIG. 11B also operates in this example. Since C_{1.1} may be correlated with parasitic capacitance as in [Equation 12], v_{bg} is identified as also satisfying v_{cal}≈0 for the calibration of C_{1.1}. In addition, the following relationship may be concluded to satisfy v_{cal}=0 in [Equation 12].

$${\overline{C}}_{1.1} = {\overline{C}}_{1.} + {\overline{C}}_{2.} - \frac{{C}_{pb 1.1} {C}_{pt \text{.1} \text{.1}} - ( {C}_{pt \text{.1} \text{.0}} + {C}_{pt \text{.2} \text{.0}} ) ( {C}_{pb 1.} + {C}_{pb 2.} )}{{\check{C}}_{pt} + {\check{C}}_{pb}} \qquad [ Equation 13 ]$$

All other calibration sequences in FIG. 8 may also be processed similarly. It may be observed in FIG. 8 that one reference capacitor (or two) is used for odd-numbered (or even-numbered) calibration sequences. In summary, the calibration method proposed in the present invention updates all capacitances so that they are in a binary weighted relationship using only one or two reference capacitors based on the actual manufactured LSB capacitor C_{1.0}, instead of forcibly updating each capacitance to a specific value predefined by the design specification. In addition, the method proposed in the present invention is performed essentially when all power is turned on, as is the case with all other foreground self-calibration methods.

Generally, capacitor mismatch of the CDAC in SAR ADC degrades a signal-to-noise ratio (SNR) result, thereby reducing an effective number of bits (ENOB). As discussed above, the voltage generation circuit is used to find the accurate v_{bg} for linear search. The value of v_{bg} required for linear search is applied to each MOSCAP to set it to the accurate capacitance. As a result, capacitor mismatch should be greatly mitigated, resulting in higher SNR or ENOB that may be the most achievable resolution in the ADC.

The application domains where the calibration technique proposed in the present invention is most suitably applied may be considered as three specifications of an ADC. Since the calibration technique proposed in the present invention calibrates CDAC, SAR ADC, pipeline ADC, two-step ADC, and sub-ranging ADC that may apply CDAC are suitable architectures. High-resolution ADCs are suitable because they require more calibration compared to low-resolution ADCs. Sampling rates from approximately 1 MSPS to tens of MSPS are suitable because they may be determined by the above two conditions according to ADC trends.

Several advantages of the calibration technique proposed in the present invention are summarized as follows:
The calibration technology proposed in the present invention does not require an adaptive algorithm, e.g., LMS algorithm, thus does not require a heavy computational process, and the digital hardware logic for computation, i.e., the calibration unit, may be made much simpler.
The calibration technique proposed in the present invention does not require a dummy unit capacitor (e.g., Cao) using a 2-ADC channel configuration. In the case of the calibration technique proposed in the present invention, two unit capacitors may be used in two original ADC channels, thereby facilitating capacitance calculation based on powers of 2 without a dummy unit capacitor, as shown in FIG. 8.
Using a small number of reference capacitors (up to two), the calibration technique proposed in the present invention enables simple connections between capacitors and simple calculations of the calibration unit to be performed. For 4-bit, 8-bit, 12-bit, 16-bit, and 18-bit ADCs, respectively, the calibration techniques proposed in the present invention use only 50%, 31%, 22%, 17%, and 14% of the reference capacitors required in the conventional technology

$$( i . e . , ( 3 N - 2 ) / ( \frac{{N}^{2} + N}{2} ) \times 100 ) .$$

Therefore, as the resolution of the ADC increases, there are more capacitors, so the proposed calibration method may significantly reduce the complexity of capacitor connections and calculation processes in the calibration unit.

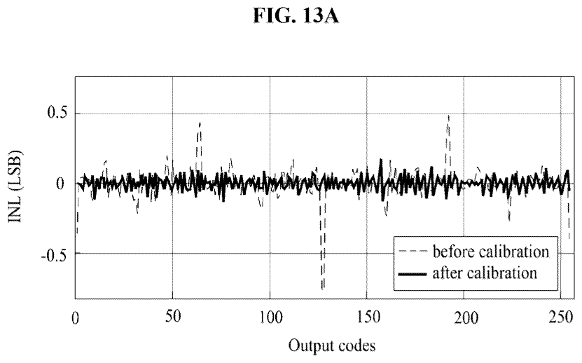

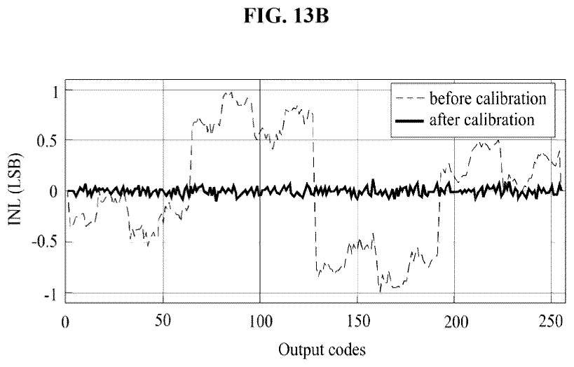

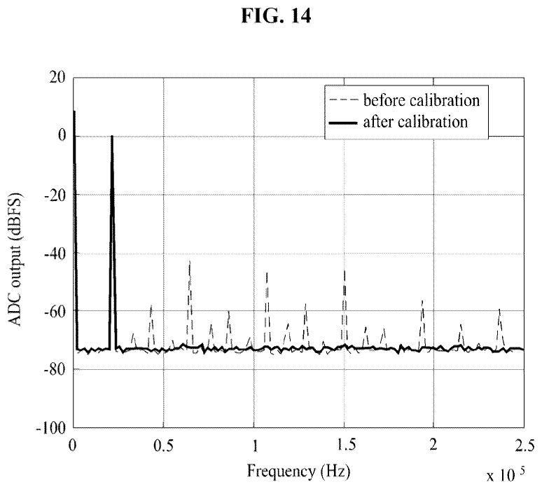

FIGS. 13A and 13B show each graph illustrating the results of the DNL and INL plots measured before and after applying the foreground self-calibration technique proposed in the present invention, and FIG. 14 shows a graph illustrating the spectrum response results measured before and after applying the foreground self-calibration technique proposed in the present invention.

To verify the performance of the foreground self-calibration technique proposed in the present invention described above, operational simulation was performed using MATLAB. In the foreground self-calibration configuration proposed in the present invention, the capacitor array of the CDAC was modeled as a nonlinear MOSCAP, and the proposed calibration unit was constructed. The capacitance range of the MOSCAP used in the simulation was assumed to be 40% of the average capacitance, the capacitor mismatch was set between 4% and 8%, and the standard variability of each capacitor was set to 1%, the same as that of conventional capacitors.

The foreground self-calibration process proposed in the present invention was performed in order from the LSB capacitor to the MSB capacitor, and the main performance of the ADC was measured before and after its application. These results are shown in FIGS. 13A and 13B and FIG. 14.

In all graphs, the legend “before calibration” represents the results measured from an uncalibrated conventional (single channel) Charge-Sharing SAR ADC, and “after calibration” represents the results obtained by the technique of the present invention. The same capacitor mismatch was applied to the ADC used for both results before and after calibration.

In order to evaluate the static performance of the calibrated ADC in the present invention, ramp signals were applied to both a single CS-SAR ADC (before calibration) and the proposed calibration-applied split ADC (after calibration) using conventional histogram-based differential nonlinearity (DNL) and integral nonlinearity (INL) methods. The outputs of each ADC were captured to obtain code widths converted to histogram results. Their DNL and INL results are shown in FIGS. 13A and 13B. The DNL and INL results before calibration are very poor compared to the results after calibration. In particular, high peaks are observed around the MSB and MSB−1 codes (e.g., center codes, etc.) in the DNL plot because mismatches in the MSB and MSB−1 capacitors typically have a significant impact on the overall performance of the ADC. Accordingly, abrupt changes also appear in the corresponding output codes of the INL plot.

To measure the dynamic performance of the ADC calibrated by the foreground self-calibration method proposed in the present invention, conventional DSP-based testing and coherent sampling were used. A single-tone sine signal of 21.5 kHz was applied to both a single ADC (before calibration) and a split ADC where the technique of the present invention was applied (after calibration). The stimulus signal was set to −1 dBFS to prevent clipping of the output signal. Each ADC captured a total of 2⁹ samples at 1−MSPS. The spectral response of each ADC is shown in FIG. 14. In addition, total harmonic distortion (THD) results were obtained using harmonic coefficients up to the 10th order. It is evident that SNR, THD, and signal-to-noise and distortion ratio (SINAD) were significantly improved by the foreground self-calibration method proposed in the present invention. Therefore, it can be seen that the foreground self-calibration method proposed in the present invention can be practically used as a foreground self-calibration solution suitable for SAR ADCs.

The system or device described above may be implemented with hardware components, software components, and/or a combination of hardware components and software components. For example, the devices and components described in the embodiments may be implemented using one or more general-purpose computers or special-purpose computers, such as a processor, controller, ALU (arithmetic logic unit), digital signal processor, microcomputer, FPGA (Field Programmable Gate Array), PLU (programmable logic unit), microprocessor, or any other device capable of executing and responding to instructions. The processing device may execute an operating system (OS) and one or more software applications running on the operating system. Additionally, the processing device may access, store, manipulate, process, and generate data in response to execution of software. For convenience of understanding, although a processing device may be described as being used singularly, those skilled in the art will understand that the processing device may include multiple processing elements and/or multiple types of processing elements. For example, the processing device may include multiple processors or one processor and one controller. Other processing configurations, such as parallel processors, are also possible.

Software may include a computer program, code, instructions, or a combination of one or more thereof, and may configure a processing device to operate as desired or may instruct the processing device independently or collectively. Software and/or data may be permanently or temporarily embodied in any type of machine, component, physical device, virtual equipment, computer storage medium or device, or transmitted signal wave, for interpretation by a processing device or for providing instructions or data to a processing device. Software may be distributed over networked computer systems and may be stored or executed in a distributed manner. Software and data may be stored on one or more computer-readable recording media.

The method according to the embodiment may be implemented in the form of program instructions that can be executed through various computer means and recorded on a computer-readable medium. The computer-readable medium may include program instructions, data files, data structures, etc., alone or in combination. The program instructions recorded on the medium may be specially designed and configured for the embodiment or may be known and available to those skilled in computer software. Examples of computer-readable recording media include hardware devices specially configured to store and execute program instructions, such as hard disks, magneto-optical media, solid-state drives (SSDs), and ROM, RAM, flash memory, etc. Examples of program instructions include machine language code such as that created by a compiler as well as high-level language code that can be executed by a computer using an interpreter, etc. The above-described hardware devices may be configured to operate as one or more software modules to perform the operations of the embodiment, and vice versa.

Although the embodiments have been described above with reference to limited embodiments and drawings, various modifications and variations are possible from the above description by those having ordinary knowledge in the relevant technical field. For example, appropriate results may be achieved even if the described techniques are performed in a different order than the described method, and/or components of the described system, structure, device, circuit, etc. are combined or combined in a different form than the described method, or are replaced or substituted by other components or equivalents.

Therefore, other implementations, other embodiments, and equivalents to the claims also fall within the scope of the following claims.

What is claimed is:

1. A foreground self-calibration method for a split successive-approximation register analog-to-digital converter (SAR ADC) comprising at least one processor, the method comprising:
a precharge step of setting an initial state of binary-weighted capacitors configured in a first ADC channel and a second ADC channel; and
a capacitance-calibration step of sequentially calibrating the binary-weighted capacitors of the first ADC channel and the second ADC channel by connecting the binary-weighted capacitors in a parallel connection or an antiparallel connection.

2. The foreground self-calibration method of claim 1, wherein
the precharge step deactivates a first comparator and a second comparator by connecting para-switches of all binary-weighted capacitors of the first ADO channel and the second ADC channel in a parallel connection, and precharges all of the binary-weighted capacitors by a reference voltage (V_{REF}).

3. The foreground self-calibration method of claim 1, wherein
the capacitance-calibration step sequentially calibrates a binary-weighted capacitors of the first ADC channel and the second ADO channel from a least significant bit (LSB) capacitor to a most significant bit (MSB) capacitor so as to construct binary-weighted relationships of all capacitors.

4. The foreground self-calibration method of claim 1, wherein
the capacitance calibration step uses one reference capacitor of the first ADO channel to calibrate one specific capacitor of the second ADO channel in odd-numbered calibration sequences, and uses two reference capacitors from the first ADC channel and the second ADC channel to calibrate capacitor of the first ADC channel in even-numbered calibration sequences.

5. The foreground self-calibration method of claim 4, wherein
the capacitance-calibration step updates all capacitances so as to satisfy a binary-weighted relationship by using only one or two of the reference capacitors.

6. The foreground self-calibration method of claim 4, wherein
the capacitance-calibration step comprises:
connecting the specific capacitor and the reference capacitor to a top plate and a bottom plate in a parallel connection or an antiparallel connection to calibrate the specific capacitor;
setting para-switches of other capacitors of the first ADC channel and the second ADO channel to a non-connected state;
acquiring a calibration reference signal by using a first comparator from a voltage difference between the top plate and the bottom plate; and
updating a value of the specific capacitor based on the calibration reference signal.

7. The foreground self-calibration method of claim 6, wherein
the connecting comprises connecting p switches of the specific capacitor and the reference capacitor in the first ADC channel and the second ADC channel to the top plate and the bottom plate in a parallel connection or an antiparallel connection.

8. The foreground self od of claim 1, wherein
the first ADC channel and the second ADC channel are configured as successive approximation reg converters (SAR ADCs).

9. The foreground self-calibration method of claim 1, wherein
the first ADC channel and the second ADC channel comprise a capacitive digital-to-analog converter (CDAC) comprising a binary-weighted capacitor array configured as variable capacitors.

10. A foreground self-calibration apparatus for a split successive-approximation register analog-to-digital converter (SAR ADC), the apparatus comprising:
a precharge unit configured to set an initial state of binary-weighted capacitors configured in a first ADC channel and a second ADC channel; and
a capacitance-calibration unit configured to sequentially calibrate the binary-weighted capacitors of the first ADC channel and the second ADC channel by connecting the binary-weighted capacitors in a parallel connection or an antiparallel connection.

11. The foreground apparatus of claim 10, wherein
the precharge unit deactivates a first comparator and a second comparator by connecting para-switches of all binary-weighted capacitors in the first ADC channel and the second ADC channel in a parallel connection, and precharges all of the binary-weighted capacitors by a reference voltage (V_{REF}).

12. The foreground self-calibration apparatus of claim 10, wherein
the capacitance-calibration unit sequentially calibrates all binary-weighted capacitors of the first ADC channel and the second ADC channel from a least significant bit (LSB) capacitor to a most significant bit (MSB) capacitor so as to construct binary-weighted relationships of all capacitors.

13. The foreground s of claim 10, wherein
the capacitance-calibration unit uses one reference capacitor of the first ADC channel to calibrate one specific capacitor of the second ADC channel in odd-numbered calibration sequences, and uses two reference capacitors from the first ADC channel and the second ADC channel to calibrate one specific capacitor of the first ADC channel in even-numbered calibration sequences.

14. The foreground self-calibration apparatus of claim 13, wherein
the capacitance-calibration unit is configured to: connect the specific capacitor and the reference capacitor to the top plate and to bottom plate in the parallel connection or antiparallel connection to calibrate the specific capacitor; set para-switches of all other capacitors of the first ADC channel and the second ADC channel to non-connected state; acquire a calibration reference signal by using a first comparator from a voltage difference between the top plate and the bottom plate; and update a value of the specific capacitor based on the calibration reference signal.
